(19) United States
(12) Patent Application Publication
(10) Pub. No.: US 2025/0210547 A1
(43) Pub. Date: Jun. 26, 2025

(54) SEMICONDUCTOR PACKAGE INCLUDING AN ELECTROMAGNETIC SHIELD AND METHOD OF FABRICATING THE SAME

(71) Applicant: SAMSUNG ELECTRONICS CO., LTD., SUWON-SI (KR)

(72) Inventor: Byoung-Gug MIN, Suwon-si (KR)

(21) Appl. No.: 18/739,950

(22) Filed: Jun. 11, 2024

(30) Foreign Application Priority Data
Dec. 26, 2023 (KR) 10-2023-0191432

(51) Int. Cl. H01L 23/60; H01L 23/528; H01L 25/065

(52) U.S. Cl. CPC H01L 23/60; H01L 23/5286; H01L 25/0657; H01L 2225/0651

(57) ABSTRACT

A semiconductor package is capable of reducing electromagnetic interference (EMI). The semiconductor package includes a circuit board, semiconductor chips mounted on the circuit board, a molding formed on the circuit board and covering each of the semiconductor chips, an electromagnetic shield formed on the circuit board and covering the molding and ground wires connected to ground pads, which are installed on the circuit board. The ground wires penetrate the molding and the electromagnetic shield.

### CROSS-REFERENCE TO RELATED APPLICATION

This application claims priority under 35 U.S.C. § 119 to Korean Patent Application No. 10-2023-0191432, filed on Dec. 26, 2023 in the Korean Intellectual Property Office, the contents of which in its entirety are herein incorporated by reference.

### TECHNICAL FIELD

The present disclosure relates to a semiconductor package and, more particularly, to a semiconductor package including an electromagnetic shield and a method of fabricating the same.

### DISCUSSION OF THE RELATED ART

Recently, as processing technology has become more sophisticated and more diversified, the size of semiconductor chips has decreased, and the number of input/output terminals of the semiconductor chips has increased, leading to the finer pitch of electrode pads. Moreover, with the accelerated integration of various functions, system-level packaging technology, which integrates multiple devices within a single package, is emerging.

However, as the operating speed of electronic components increases and a variety of functions are added, system-level packaging technology faces challenges such as the occurrence of electromagnetic interference (EMI) between components, giving rise to additional processes for addressing such challenges.

### SUMMARY

A semiconductor package includes a circuit board, semiconductor chips mounted on the circuit board, a molding formed on the circuit board and covering each of the semiconductor chips, an electromagnetic shield formed on the circuit board and covering the molding and ground wires connected to ground pads, which are installed on the circuit board. The ground wires penetrate the molding and the electromagnetic shield.

A semiconductor package includes a circuit board including a center area and a peripheral area, semiconductor chips mounted on the center area, a molding formed on the circuit board, covering each of the semiconductor chips, and including a groove, which is formed at opposite ends of the molding, an electromagnetic shield formed on the circuit board, filling the groove, and covering an upper surface of the molding and ground wires installed in the peripheral area and connected to ground pads, which are installed on the circuit board, the ground wires including first portions, which penetrate the molding, and second portions, which penetrate parts of the electromagnetic shield formed in the groove. The electromagnetic shield exposes the second portions.

A method of fabricating a semiconductor package includes providing a circuit board, which extends in a first direction, first semiconductor chips, which are disposed on the circuit board, second semiconductor chips, which are spaced apart from the first semiconductor chips in the first direction, on the circuit board, and ground wires, which are connected to ground pads that are installed on the circuit board. A molding is formed on the circuit board and covers the first semiconductor chips, the second semiconductor chips, and the ground wires. A groove is formed on opposite ends of the molding, between the first semiconductor chips and the second semiconductor chips, in the molding through a laser drilling process. The groove exposes the ground wires and forms an electromagnetic shield, which covers an upper surface of the molding, fills the groove, and envelops the ground wires in the groove.

### BRIEF DESCRIPTION OF THE DRAWINGS

The above and other aspects and features of the present disclosure will become more apparent by describing in detail example embodiments thereof with reference to the attached drawings, in which:

FIG. 1 is a plan view illustrating a semiconductor package according to embodiments

of the present disclosure;

FIG. 2 is a cross-sectional view taken along line A-A of FIG. 1;

FIG. 3 is a cross-sectional view taken along line B-B of FIG. 1;

FIG. 4 is a plan view illustrating a semiconductor package according to embodiments of the present disclosure;

FIG. 5 is a plan view of part P of FIG. 4;

FIG. 6 is a cross-sectional view taken along line C-C of FIG. 5;

FIGS. 7, 8, 9, 10, and 11 are cross-sectional views illustrating a method of fabricating a semiconductor package according to embodiments of the present disclosure;

FIGS. 12 through 14 are drawings illustrating semiconductor packages according to embodiments of the present disclosure;

FIG. 15 is a cross-sectional view illustrating a semiconductor package according to embodiments of the present disclosure; and

FIGS. 16 and 17 are drawings illustrating a semiconductor package according to embodiments of the present disclosure.

### DETAILED DESCRIPTION

In this specification, although terms such as “first,” “second,” “upper,” and “lower” are used to describe various elements or components, these elements or components are not necessarily limited by these terms. These terms may be used to distinguish one element or component from another. Therefore, a first element or component mentioned below may be a second element or component within the technical spirit of the present disclosure. Similarly, a lower element or component mentioned below may be an upper element or component within the technical spirit of the present disclosure.

Embodiments of the present disclosure will hereinafter be described in detail with reference to the attached drawings. The same reference numerals may be used for the same elements in the drawings and the specification, and to the extent that an element is not described in detail with respect to this figure, it may be understood that the element is at least similar to a corresponding element that has been described elsewhere within the present disclosure.

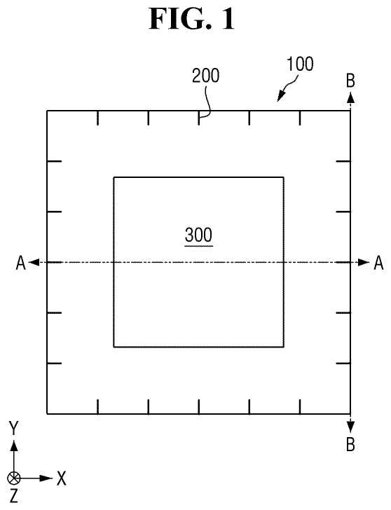

A semiconductor package according to embodiments of the present disclosure will hereinafter be described with reference to FIGS. 1 through 3.

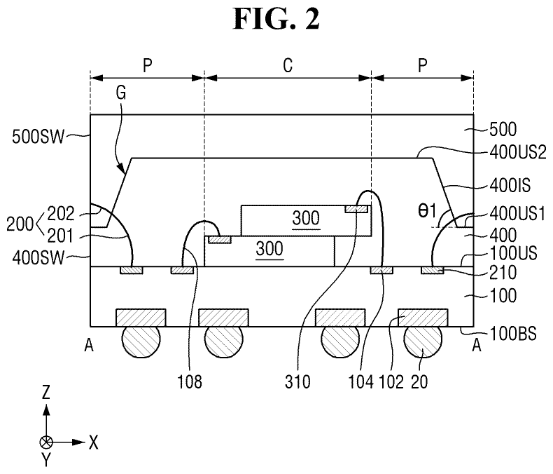

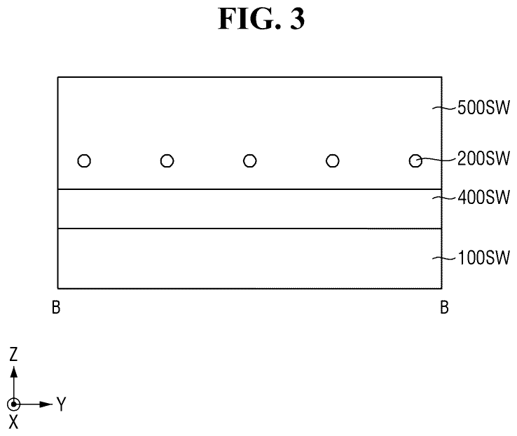

FIG. 1 is a plan view illustrating a semiconductor package according to embodiments of the present disclosure. FIG. 2 is a cross-sectional view taken along line A-A of FIG. 1. FIG. 3 is a cross-sectional view taken along line B-B of FIG. 1.

Referring to FIGS. 1 and 2, the semiconductor package, according to embodiments of the present disclosure, may include a circuit board 100, semiconductor chips 300, ground wires 200, a molding 400, and an electromagnetic shield 500.

The circuit board 100 may extend in a first direction X. In this specification, the first direction X, a second direction Y, and a third direction Z may intersect one another. The first, second, and third directions X, Y, and Z may be substantially perpendicular to one another.

The circuit board 100 may include a center area C and a peripheral area P. The center area C may be the central area of the circuit board 100. The center area C may be at least partially surrounded by the peripheral area P. The semiconductor chips 300, which will be described later, may be disposed in the center area C.

The peripheral area P may account for the entire area of the circuit board 100 except for the center area C. The ground wires 200, which will be described later, may be installed at the edges of the peripheral area P.

The circuit board 100 may be a substrate for packaging. The circuit board 100 may be a printed circuit board (PCB). The circuit board 100 may include upper and lower surfaces 100US and 100BS, which are opposite to each other.

The circuit board 100 may include first substrate pads 102 and second substrate pads

104. The first substrate pads 102 and the second substrate pads 104 may be used to electrically connect the circuit board 100 to other components. In embodiments, the first substrate pads 102 may be formed near the lower surface 100BS of the circuit board 100, and the second substrate pads 104 may be formed near the upper surface 100US of the circuit board 100.

The circuit board 100 may be mounted on the mainboard of an electronic device. For example, solder balls 20, which are connected to the first substrate pads 102, may be provided. The circuit board 100 may be mounted on the mainboard of an electronic device through the solder balls 20. The circuit board 100 may be a ball grid array (BGA) board, but the present disclosure is not necessarily limited thereto.

The solder balls 20 may be solder bumps including a low melting point metal, such as tin (Sn) and a Sn alloy, but the present disclosure is not necessarily limited thereto. The solder balls 20 may have various other shapes, such as a land shape, a ball shape, a pin shape, or a pillar shape, etc.

The solder balls 20 may be formed as single layers or multilayers. When formed as single layers, the solder balls 20 may include, for example, tin-silver (Sn—Ag) solder or copper (Cu). When formed as multilayers, the solder balls 20 may include, for example, a Cu pillar and solder. The number, spacing, and arrangement pattern of the solder balls 20 are not necessarily particularly limited to what is shown and may vary depending on the design.

The semiconductor chips 300 may be disposed on the circuit board 100. For example, the semiconductor chips 300 may be disposed on the upper surface 100US of the circuit board 100. The semiconductor chips 300 may be disposed in the center area C of the circuit board 100.

The semiconductor chips 300 may have a stack of two or more chips. The semiconductor chips 300 may include an adhesive layer. The semiconductor chips 300 may be bonded to the circuit board 100 through the adhesive layer. A plurality of chips may be bonded through the adhesive layer.

The adhesive layer may include, for example, a die attach film (DAF), a non-conductive film (NCF), or a non-conductive paste (NCP).

The semiconductor chips 300 may include chip pads 310. The chip pads 310 may be used to electrically connect the semiconductor chips 300 with other components. The chip pads 310 may be formed on the upper surfaces of the semiconductor chips 300. For example, the chip pads 310 may be exposed from the upper surface of the semiconductor chips 300.

The chip pads 310 may include a metal material such as, for example, aluminum (Al), copper (Cu), nickel (Ni), tungsten (W), platinum (Pt), and/or gold (Au), but the present disclosure is not necessarily limited thereto.

The chip pads 310 and the second substrate pads 104 may be connected through wires 108. A plurality of chips may be electrically connected to the circuit board 100 through the wires 108. The wires 108 may be formed of, for example, Au, Cu, silver (Ag), aluminum (Al), or a combination thereof.

The semiconductor chips 300 may be memory chips. For example, the semiconductor chips 300 may be volatile memories such as dynamic random-access memories (DRAMs) or static random-access memories (SRAMs), or nonvolatile memories such as flash memories, phase-change random-access memories (PRAMs), magnetoresistive random-access memories (MRAMs), ferroelectric random-access memories (FeRAMs), or resistive random-access memories (RRAMs). In embodiments, the semiconductor chips 300 may be stacked memories such as high bandwidth memories (HBMs).

Alternatively, the semiconductor chips 300 may be logic chips. For example, the semiconductor chips 300 may be application processors (APs) such as central processing units (CPUs), graphics processing units (GPUs), field-programmable gate arrays (FPGAs), digital signal processors, encryption processors, microprocessors, microcontrollers, or application-specific integrated circuits (ASICs), but the present disclosure is not necessarily limited thereto.

The ground pads 210 may be formed near the upper surface 100US of the circuit board 100. The ground pads 210 may be installed in the peripheral area P of the circuit board 100. The ground pads 210 may be formed on the upper surface 100US of the circuit board 100. A ground voltage may be applied to the ground pads 210.

FIG. 2 illustrates that the ground pads 210 have a rectangular shape, but the present

disclosure is not necessarily limited thereto. Alternatively, the ground pads 210 may have another polygonal shape or a circular shape.

The ground wires 200 may be installed in the peripheral area P of the circuit board 100. The ground wires 200 may be installed on the ground pads 210. The ground wires 200 may be spaced apart from the semiconductor chips 300 in the first direction X.

If one or more ground pads 210 are formed on the circuit board 100, the ground wires 200 may be disposed on each of the ground pads 210. The ground wires 200 may be formed of, for example, Au, Cu, Ag, Al, or a combination thereof.

The ground wires 200 may include first portions 201 and second portions 202.

The first portions 201 of the ground wires 200 may be connected to the ground pads 210. The first portions 201 of the ground wires 200 may contact the upper surface 100US of the circuit board 100. The first portions 201 of the ground wires 200 may be enveloped by the molding 400, which will be described later. The first portions 201 of the ground wires 200 may penetrate the molding 400.

The second portions 202 of the ground wires 200 may be enveloped by the electromagnetic shield 500, which will be described later. The second portions 202 of the ground wires 200 may penetrate the electromagnetic shield 500. The second portions 202 of the ground wires 200 may be exposed from side surface 500SW of the electromagnetic shield 500. The second portions 202 of the ground wires 200 may contact the side surface 500SW of the electromagnetic shield 500.

The first portions 201 and the second portions 202 of the ground wires 200 may meet at inclined surfaces 400IS of the molding 400. The first portions 201 and the second portions 202 of the ground wires 200 may also meet at a first upper surface 400US1 of the molding 400.

The molding 400 may be formed on the circuit board 100 and may cover parts of the semiconductor chips 300 and parts of the wires 108. The molding 400 may cover the upper and side surfaces of each of the semiconductor chips 300. The molding 400 may envelop the first portions 201 of the ground wires 200.

The molding 400 may include the first upper surface 400US1, a second upper surface 400US2, and the inclined surfaces 400IS, which connect the first and second upper surfaces 400US1 and 400US2 to one another. The molding 400 may include a groove G, which is formed at opposite ends of the molding 400.

The upper surface of the molding 400 in the groove G may be the first upper surface 400US1. The first upper surface 400US1 may be lower than the second upper surface 400US2 relative to the upper surface 100US of the circuit board 100. The first and second upper surfaces 400US1 and 400US2 may be parallel.

The first upper surface 400US1 may overlap with the second portions 202 of the ground wires 200 in the third direction Z. The first upper surface 400US1 may correspond to the boundaries between the first portions 201 and the second portions 202 of the ground wires 200.

The first upper surface 400US1 is illustrated in FIG. 2 as being a flat surface, but the present disclosure is not necessarily limited thereto. Alternatively, the first upper surface 400US1 may be a convex or concave curved surface.

The inclined surfaces 400IS may connect the first and second upper surfaces 400US1 and 400US2. The inclined surfaces 400IS may correspond to the boundaries between the first portions 201 and the second portions 202 of the ground wires 200. A first angle θ formed between the inclined surfaces 400IS and an imaginary extension of the first upper surface 400US1 may be an acute angle, but the present disclosure is not necessarily limited thereto. Alternatively, the first angle θ may be a right angle.

The groove G may be defined by the first upper surface 400US1 and the inclined surfaces 400IS. The groove G may be formed through a method such as laser drilling, mechanical drilling, plasma etching, or chemical etching. In embodiments, the groove G may be formed by a laser drilling process.

Side surface 400SW of the molding 400 might not be covered by the electromagnetic shield 500. The side surface 400SW of the molding 400 may be exposed. The side surface 400SW of the molding 400 may lie in the same plane as corresponding side surface 100SW of the circuit board 100. The side surface 400SW of the molding 400 may also lie in the same plane as the corresponding side surface 500SW of the electromagnetic shield 500.

The side surface 400SW of the molding 400 may be perpendicular to the first and second upper surfaces 400US1 and 400US2. The angle formed between the side surface 400SW of the molding 400 and the inclined surfaces 400IS may be an acute angle or a right angle.

The molding 400 may include an insulating polymer material such as an epoxy mold compound (EMC), but the present disclosure is not necessarily limited thereto. For example, the molding 400 may include an epoxy-based resin, benzocyclobutene (BCB), or polyimide. As another example, the molding 400 may include a silica filler or flux.

The electromagnetic shield 500 may be formed on the circuit board 100. The electromagnetic shield 500 may be formed on the molding 400. The electromagnetic shield 500 may cover the upper surface of the molding 400. The electromagnetic shield 500 may fill the groove G formed in the molding 400.

The electromagnetic shield 500 may cover the first upper surface 400US1, the second upper surface 400US2, and the inclined surfaces 400IS of the molding 400, but might not cover the side surface 400SW of the molding 400. For example, the electromagnetic shield 500 may expose the side surface 400SW of the molding 400.

The electromagnetic shield 500 may envelop the second portions 202 of the ground wires 200. The electromagnetic shield 500 may expose the ground wires 200. For example, the ground wires 200 may be exposed at the side surface 500SW of the electromagnetic shield 500. For example, the second portions 202 of the ground wires 200 may be exposed at the side surface 500SW of the electromagnetic shield 500. The ground wires 200 may contact the side surface 500SW of the electromagnetic shield 500.

The electromagnetic shield 500 may include a conductive material. In embodiments, the electromagnetic shield 500 may include a metal. For example, the electromagnetic shield 500 may include Cu, Ag, etc. In this example, the electromagnetic shield 500 may be formed by a sputtering process or an inkjet process.

The electromagnetic shield 500 may include a binder resin that maintains the form of a film. The electromagnetic shield 500 may include, as a binder resin, a resin primarily composed of acrylic resin or its modified forms. The electromagnetic shield 500 may include a thermosetting material such as ethylene oxide. The electromagnetic shield 500 may include a stretchable material such as thermoplastic polyurethane (TPU) and may further include butadiene, nitrile, chloroprene, or isoprene to enhance stretchability. The electromagnetic shield 500 may be a mixed resin of ethylene oxide and TPU. In this case, the electromagnetic shield 500 may be formed by a spraying process.

Referring to FIG. 3, in the semiconductor package, according to embodiments of the present disclosure, the circuit board 100, the molding 400, and the electromagnetic shield 500, which envelops the ground wires 200, may be sequentially stacked. On the side surface of the semiconductor package according to embodiments of the present disclosure, the side surface 100SW of the circuit board 100, the side surface 400SW of the molding 400, the side surface 500SW of the electromagnetic shield 500, and first surface 200SW of the ground wires 200 may overlap with one another in the third direction Z.

In embodiments, the side surface 400SW of the molding 400, the first surface 200SW of the ground wires 200, exposed from the electromagnetic shield 500, and the side surface 500SW of the electromagnetic shield 500 may lie in common planes.

The first surface 200SW of the ground wires 200 may be spaced apart from the side surface 400SW of the molding 400 in the third direction Z.

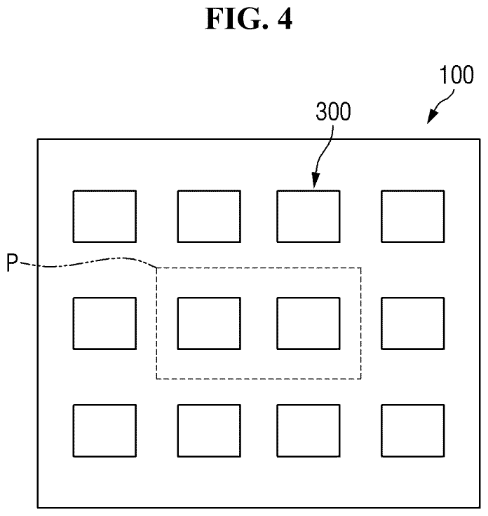

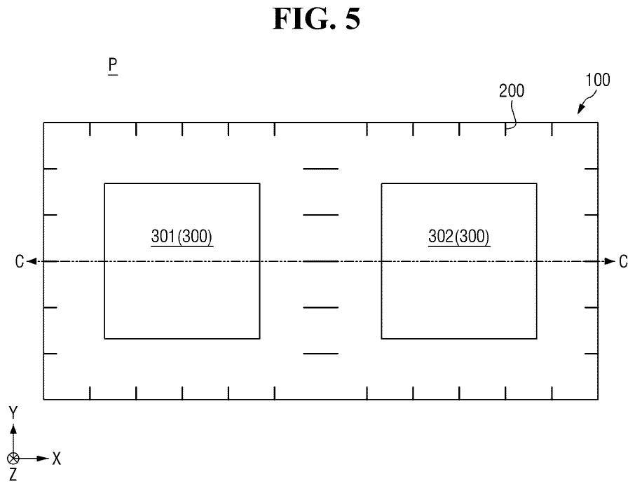

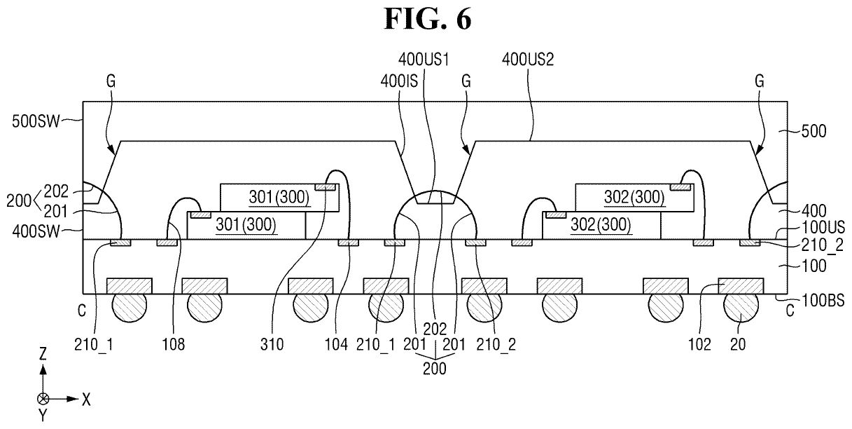

FIG. 4 is a plan view illustrating a semiconductor package according to embodiments of the present disclosure. FIG. 5 is a plan view of part P of FIG. 4. FIG. 6 is a cross-sectional view taken along line C-C of FIG. 5. To the extent that an element is not described in detail with respect to this figure, it may be understood that the element is at least similar to a corresponding element that has been described elsewhere within the present disclosure, for example, what has been described above with reference to FIGS. 1 through 3.

Referring to FIGS. 4 through 6, the semiconductor package, according to embodiments of the present disclosure, may include a circuit board 100, first semiconductor chips 301, second semiconductor chips 302, ground wires 200, a molding 400, and an electromagnetic shield 500.

The circuit board 100 may extend in a first direction X. Second substrate pads 104, first ground pads 210_1, and second ground pads 210_2 may be installed on an upper surface 100US of the circuit board 100. First substrate pads 102 may be installed on a lower surface 100US of the circuit board 100.

The second substrate pads 104 may be connected with wires 108, which connect the circuit board 100 to either the first semiconductor chips 301 or the second semiconductor chips 302. The first ground pads 210_1 and the second ground pads 210_2 may be connected with the ground wires 200. The first substrate pads 102 may be connected with solder balls 20, which are disposed on the lower surface 100BS of the circuit board 100.

The first semiconductor chips 301 may be disposed on the upper surface 100US of the circuit board 100. The first semiconductor chips 301 may include chip pads 310. The first semiconductor chips 301 may be electrically connected to the circuit board 100 through the wires 108, which connect the chip pads 310 and the second substrate pads 104 to one another.

The second semiconductor chips 302 may be disposed on the upper surface 100US of the circuit board 100. The second semiconductor chips 302 may be spaced apart from the first semiconductor chips 301 in the first direction X. The second semiconductor chips 302 may be electrically connected to the circuit board 100 through the wires 108, which connect the chip pads 310 and the second substrate pads 104 to one another. The second semiconductor chips 302 and the first semiconductor chips 301 may all be the same chips (dies).

The molding 400 may be formed on the circuit board 100. The molding 400 may cover the first semiconductor chips 301 and the second semiconductor chips 302. For example, the molding 400 may cover the upper and side surfaces of each of the first semiconductor chips 301 and the upper and side surfaces of each of the semiconductor chips 302.

The molding 400 may include a first upper surface 400US1, a second upper surface 400US2, which is higher than the first upper surface 400US1, and inclined surfaces 400IS, which connect the first and second upper surfaces 400US1 and 400US2 to one another.

The molding 400 may include a groove G, which is defined by the first upper surface 400US1 and the inclined surfaces 400IS.

The groove G may be formed between the first semiconductor chips 301 and the second semiconductor chips 302. The groove G may be formed through a method such as laser drilling, mechanical drilling, plasma etching, or chemical etching. In embodiments, the groove G may be formed by a laser drilling process.

The width of the groove G may decrease closer to the upper surface 100US of the circuit board 100. The groove G might not meet the upper surface 100US of the circuit board 100. For example, the molding 400 might not be separated by the groove G.

The groove G may expose parts of ground wires 200. For example, the groove G may expose second portions 202 of the ground wires 200 from the molding 400.

The groove G may be formed at opposite ends of the molding 400. For example, the groove G may be spaced apart from the first semiconductor chips 301 in the first direction X. The groove G may also be spaced apart from the second semiconductor chips 302 in the first direction X.

The ground wires 200 may be installed on the upper surface 100US of the circuit

board 100. The ground wires 200 may be connected to the first ground pads 210_1. The ground wires 200 may also be connected to the second ground pads 210_2.

In embodiments, the ground wires 200 may be installed between the first semiconductor chips 301 and the second semiconductor chips 302. In this case, first ends of the ground wires 200 may be connected to the first ground pads 210_1, and second ends of the ground wires 200 may be connected to the second ground pads 210_2. The ground wires 200 may penetrate the groove G. The ground wires 200 may also penetrate the electromagnetic shield 500, which fills the groove G. For example, the second portions 202 of the ground wires 200 may penetrate the groove G. The first portions 201 of the ground wires 200 may be within the molding 400, and the second portions 202 of the ground wires 200 may be outside the molding 400. For example, the first portions 201 of the ground wires 200 may be within the molding 400, and the second portions 202 of the ground wires 200 may be within the electromagnetic shield 500.

In embodiments, the ground wires 200 may be installed at opposite ends of the molding 400. In this case, the first ends of the ground wires 200 may be connected to the first ground pads 210_1, and the second ends of the ground wires 200 may be connected to side surface 500SW of the electromagnetic shield 500. For example, the first ends of the ground wires 200 may contact the upper surface 100US of the circuit board 100, and the second ends of the ground wires 200 may contact the side surface 500SW of the electromagnetic shield 500.

The ground wires 200 may penetrate the groove G. For example, the second portions 202 of the ground wires 200 may penetrate the groove G and meet the side surface 500SW of the electromagnetic shield 500. In this example, the first portions 201 of the ground wires 200 may be within the molding 400, and the second portions 202 of the ground wires 200 may be within the electromagnetic shield 500.

The electromagnetic shield 500 may be disposed on the circuit board 100. The electromagnetic shield 500 may fill the groove G. The electromagnetic shield 500 may cover the first upper surface 400US1, the inclined surfaces 400IS, and the second upper surface 400US2 of the molding 400. However, the electromagnetic shield 500 might not cover the side surface 400SW of the molding 400.

The electromagnetic shield 500 may cover parts of the ground wires 200 in the groove G. For example, the electromagnetic shield 500 may cover the second portions 202 of the ground wires 200 in the groove G. The electromagnetic shield 500 may envelop the second portions 202 of the ground wires 200 in the groove G.

The electromagnetic shield 500 may overlap with the second portions 202 of the ground wires 200 in a third direction Z. The second portions 202 of the ground wires 200 may be exposed from the side surface 500SW of the electromagnetic shield 500.

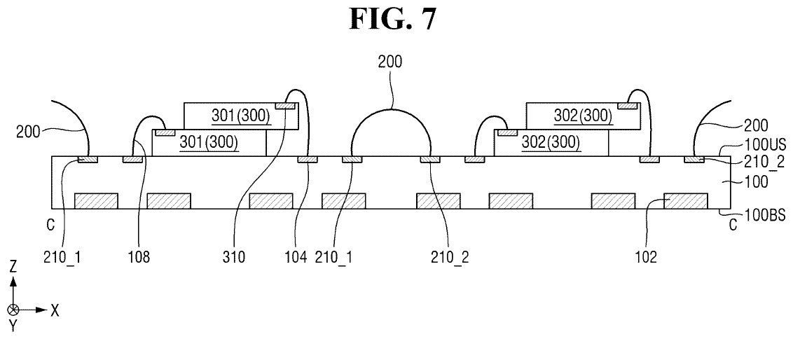

FIGS. 7 through 11 are cross-sectional views illustrating a method of fabricating a semiconductor package according to embodiments of the present disclosure. To the extent that an element is not described in detail with respect to this figure, it may be understood that the element is at least similar to a corresponding element that has been described elsewhere within the present disclosure, for example, with respect to FIGS. 1 through 6.

Referring to FIG. 7, a circuit board 100, first semiconductor chips 301, which are disposed on an upper surface 100US of the circuit board 100, second semiconductor chips 302, which are disposed on the upper surface 100US of the circuit board 100 and spaced apart from the first semiconductor chips 301 in a first direction X, and ground wires 200, which are connected to first ground pads 210_1 and second ground pads 210_2 on the circuit board 100, may be provided.

The circuit board 100 may include first substrate pads 102, which are installed on a lower surface 100BS of the circuit board 100, and second substrate pads 104 and ground pads 210, which are installed on the upper surface 100US of the circuit board 100.

The first semiconductor chips 301, the second semiconductor chips 302, and the circuit board 100 may be electrically connected through wires 108, which connect the second substrate pads 104 and chip pads 310, that are installed on the first semiconductor chips 301 and the second semiconductor chips 302, to one another.

The ground wires 200 may be electrically connected to the first ground pads 210_1 and the second ground pads 210_2. The ground wires 200 may be electrically connected to a ground voltage.

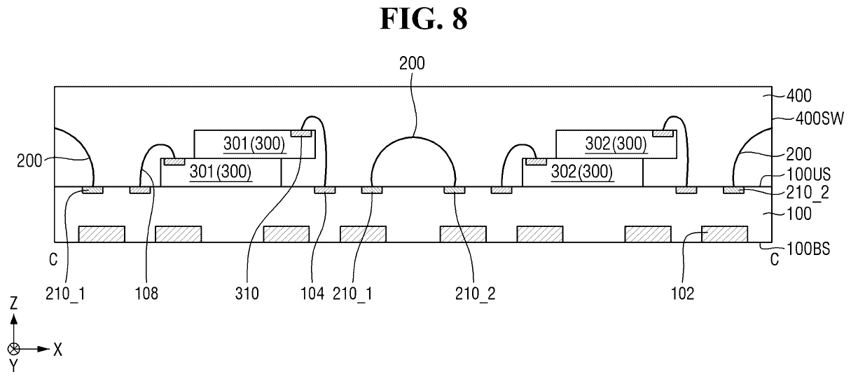

Thereafter, referring to FIG. 8, a molding 400 may be formed on the upper surface 100US of the circuit board 100.

The molding 400 may cover the first semiconductor chips 301 and the second semiconductor chips 302. For example, the molding 400 may cover the upper and side surfaces of each of the first semiconductor chips 301 and the upper and side surfaces of each of the second semiconductor chips 302.

The molding 400 may cover the ground wires 200. The molding 400 may envelop the ground wires 200.

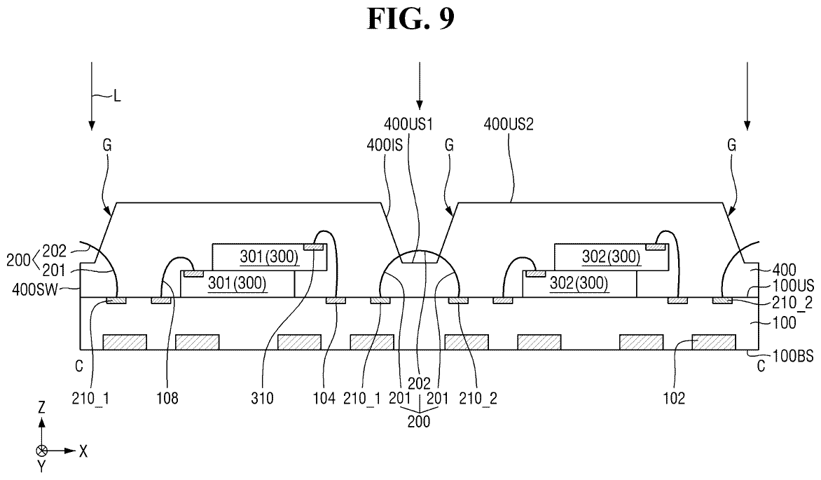

Thereafter, referring to FIG. 9, a groove G may be formed in the molding 400.

The groove G may be formed between the first semiconductor chips 301 and the second semiconductor chips 302. The groove G may be formed at opposite ends of the molding 400. The groove G may be formed using a laser drilling process L. The width of the groove G may decrease closer to the upper surface 100US of the circuit board 100.

During the formation of the groove G using the laser drilling process L, the ground wires 200 might not be severed. During the laser drilling process L, laser light may be applied in such a manner so as not to sever the ground wires 200.

The groove G may expose parts of the ground wires 200. The groove G may expose second portions 202 of the ground wires 200. Once the groove G is formed, first portions 201 of the ground wires 200 may be parts of the ground wires 200 within the molding 400, and the second portions 202 of the ground wires 200 may be parts of the ground wires 200 outside the molding 400.

The molding 400 may have the groove G formed therein, and as a result, a first upper surface 400US1, inclined surfaces 400IS, and a second upper surface 400US2 of the molding 400 may be formed.

The first upper surface 400US1 of the molding 400 may be lower in height than the second upper surface 400US2, relative to the upper surface 100US of the circuit board 100. The first upper surface 400US1 may overlap with the second portions 202 of the ground wires 200 in a third direction Z.

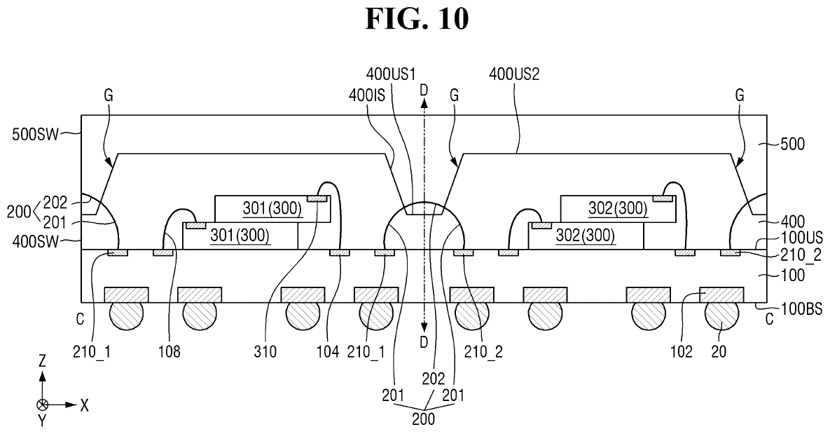

Thereafter, referring to FIG. 10, an electromagnetic shield 500, which covers the molding 400, may be formed on the upper surface 100US of the circuit board 100, and solder balls 20 may be formed on the lower surface 100BS of the circuit board 100.

The electromagnetic shield 500 may cover the first upper surface 400US1, the inclined surfaces 400IS, and the second upper surface 400US2 of the molding 400. The electromagnetic shield 500 might not cover side surface 400SW of the molding 400. The side surface 400SW of the molding 400 may be exposed from the electromagnetic shield 500.

The groove G may be filled with the electromagnetic shield 500. The second portions 202 of the ground wires 200 in the groove G may be covered by the electromagnetic shield 500. The second portions 202 of the ground wires 200 in the groove G may be enveloped by the electromagnetic shield 500.

The second portions 202 of the ground wires 200 in the groove G may be exposed from side surface 500SW of the electromagnetic shield 500. The second portions 202 of the ground wires 200 may penetrate the electromagnetic shield 500 in the groove G and may contact the side surface 500SW of the electromagnetic shield 500.

In the groove G, the electromagnetic shield 500 may be penetrated by the second portions 202 of the ground wires 200. In the groove G between the first semiconductor chips 301 and the second semiconductor chips 302, the molding 400, the electromagnetic shield 500, and the molding 400 may be sequentially penetrated by the ground wires 200.

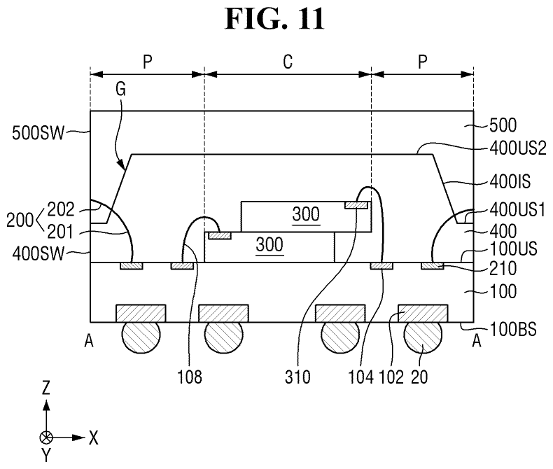

Thereafter, referring to FIGS. 10 and 11, the structure of FIG. 10 may be cut along line D-D.

Line D-D may be a scribe line. Referring to FIG. 11, a semiconductor package according to embodiments of the present disclosure, obtained by the cutting along line D-D, may include the circuit board 100, which includes a center area C and a peripheral area P, semiconductor chips 300, which are mounted in the center area C, a molding 400, which is formed on the circuit board 100, covers the semiconductor chips 300, and has a groove G formed at its opposite ends, an electromagnetic shield 500, which fills the groove G and covers the upper surface of the molding 400, and ground wires 200, which are installed in the peripheral area P, are connected to ground pads 210 on the circuit board 100, penetrate the molding 400 and the electromagnetic shield 500, and are exposed from the side surface 500SW of the electromagnetic shield 500.

A semiconductor package may include a plurality of semiconductor chips. Semiconductor chips that induce electromagnetic waves may be included in the semiconductor package. Electromagnetic waves emitted from semiconductor chips may interfere with neighboring semiconductor devices, causing noise and malfunctions. Conventionally, the upper and side surfaces of the semiconductor package are covered with an electromagnetic shield for shielding electromagnetic waves. However, completely covering the side surface of the semiconductor package with the electromagnetic shield may lead to the formation of metal burrs after detaching the semiconductor package and may complicate the formation of the electromagnetic shield.

Conversely, the semiconductor package according to embodiments of the present disclosure includes the circuit board 100, which includes the center area C and the peripheral area P, the semiconductor chips 300, which are mounted in the center area C, the molding 400, which is formed on the circuit board 100, covers the semiconductor chips 300, and has the groove G formed at its opposite ends, the electromagnetic shield 500, which fills the groove G and covers the upper surface of the molding 400, and the ground wires 200, which is installed in the peripheral area P, are connected to the ground pads 210 on the circuit board 100, penetrate the molding 400 and the electromagnetic shield 500, and are exposed from the side surface 500SW of the electromagnetic shield 500.

The groove G in the molding 400 may be formed using the laser drilling process L. The groove G may expose the ground wires 200 from the molding 400. Since the groove G is formed at opposite ends of the molding 400 and then the electromagnetic shield 500 is formed, the electromagnetic shield 500 might not entirely cover all the side surface of the semiconductor package according to embodiments of the present disclosure. Therefore, metal burrs might not occur during the detachment of the semiconductor package according to embodiments of the present disclosure after the formation of the electromagnetic shield 500.

The molding 400 may be formed, the groove G may be formed using the laser drilling process L, and then the upper surface and groove G of the molding 400 may be covered with the electromagnetic shield 500. Thus, as the electromagnetic shield 500 is formed after the formation of the groove G, the electromagnetic shield 500 may be formed by a two-step process. This can eliminate the need for side grounding on the circuit board 100 and can simplify the fabrication of the semiconductor package according to embodiments of the present disclosure.

Furthermore, the ground wires 200 may be connected to the ground pads 210 and may be disposed in the peripheral area P of the circuit board 100. The ground wires 200 may surround the semiconductor chips 300. Therefore, electromagnetic shielding can be achieved through the ground wires 200.

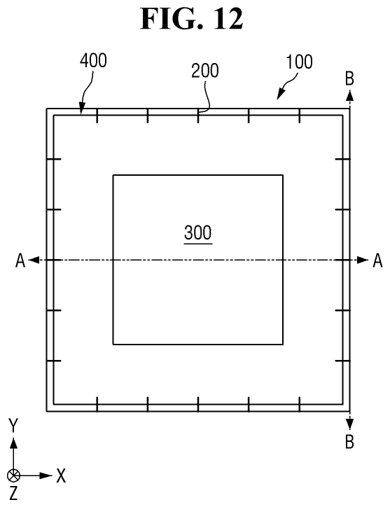

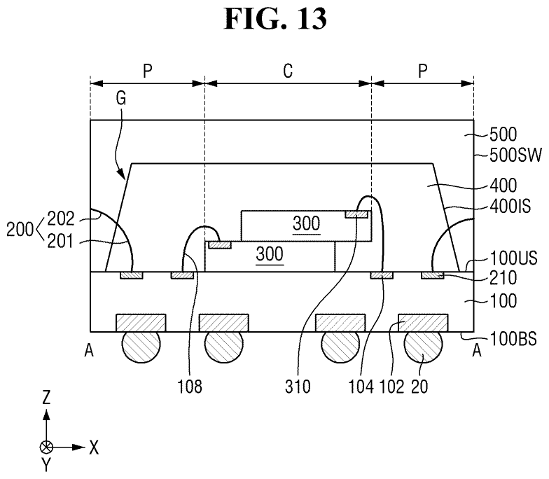

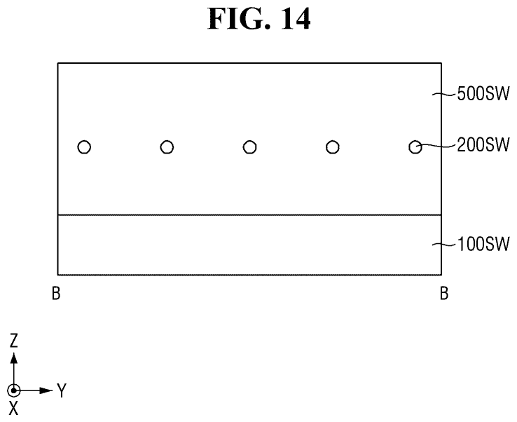

FIGS. 12 through 14 are drawings illustrating semiconductor packages according to embodiments of the present disclosure. FIG. 13 is a cross-sectional view taken along line A-A of FIG. 12. FIG. 14 is a cross-sectional view taken along line B-B of FIG. 12. To the extent that an element is not described in detail with respect to this figure, it may be understood that the element is at least similar to a corresponding element that has been described elsewhere within the present disclosure, for example, with respect to FIGS. 1 through 3.

Referring to FIGS. 12 and 13, the semiconductor package, according to embodiments of the present disclosure, may include a circuit board 100, which includes a center area C and a peripheral area P, semiconductor chips 300, which are disposed in the center area C, ground wires 200, which are disposed in the peripheral area P, a molding 400, which covers the semiconductor chips 300 and is formed on the circuit board 100, a groove G, which is formed at opposite ends of an upper surface 100US of the circuit board 100, and an electromagnetic shield 500, which is formed on the circuit board 100.

The upper surface 100US of the circuit board 100 may include the groove G at its opposite ends. The groove G may be formed by cutting through the molding 400 using a laser drilling process. The formation of the groove G may expose parts of the upper surface 100US of the circuit board 100.

The groove G may be defined by inclined surfaces 400IS of the molding 400 and the upper surface 100US of the circuit board 100 where the molding 400 is not disposed. Second portions 202 of the ground wires 200, which are positioned in the groove G, may overlap with the upper surface 100US of the circuit board 100 in a third direction Z.

The electromagnetic shield 500 may fill the groove G and may cover the upper surface of the molding 400. The electromagnetic shield 500 may fill the groove G so that parts of the upper surface 100US of the circuit board 100 may be covered by the electromagnetic shield 500.

Referring to FIG. 14, the circuit board 100 and the electromagnetic shield 500, including the ground wires 200, may be sequentially stacked. For example, side surface 100SW of the circuit board 100, first surface 200SW of the ground wires 200, exposed from the electromagnetic shield 500, and side surface 500SW of the electromagnetic shield 500 may lie in common planes. The side surface 100SW of the circuit board 100, the first surface 200SW of the ground wires 200, and the side surface 500SW of the electromagnetic shield 500 may overlap with one another in the third direction Z.

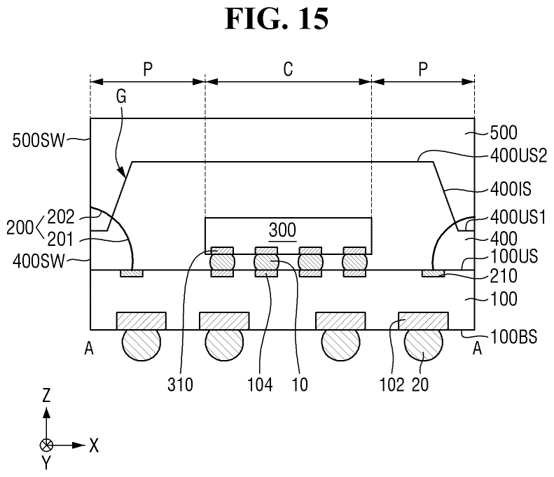

FIG. 15 is a cross-sectional view illustrating a semiconductor package according to embodiments of the present disclosure. To the extent that an element is not described in detail with respect to this figure, it may be understood that the element is at least similar to a corresponding element that has been described elsewhere within the present disclosure, for example, with respect to FIGS. 1 through 3.

Referring to FIG. 15, the semiconductor package, in embodiments of the present disclosure, may include bumps 10.

The bumps 10 may be formed between a circuit board 100 and semiconductor chips 300. The semiconductor chips 300 may include chip pads 310 on their lower surfaces. Therefore, the chip pads 310 and second substrate pads 104 may be connected through the bumps 10, allowing the semiconductor chips 300 and the circuit board 100 to be electrically connected.

The bumps 10 may be solder bumps that include a low-melting-point metal, such as Sn and a Sn alloy, but the present disclosure is not necessarily limited thereto. The bumps 10 may have various shapes, such as a land shape, a ball shape, a pin shape, or a pillar shape, etc. The bumps 10 may also include under bump metallurgies (UBMs).

The bumps 10 may be formed as single layers or multilayers. When formed as single layers, the bumps 10 may include, for example, Sn-Ag solder or Cu. When formed as multilayers, the bumps 10 may include, for example, a pillar and solder. However, the present disclosure is not necessarily limited to this. For example, the number, spacing, and arrangement pattern of the solder balls 20 are not necessarily particularly limited to what is described herein and may vary depending on the design.

The molding 400 may be formed on an upper surface 100US of the circuit board 100 and may cover the semiconductor chips 300 and the bumps 10. The molding 400 may fill the gaps between the semiconductor chips 300 and the circuit board 100.

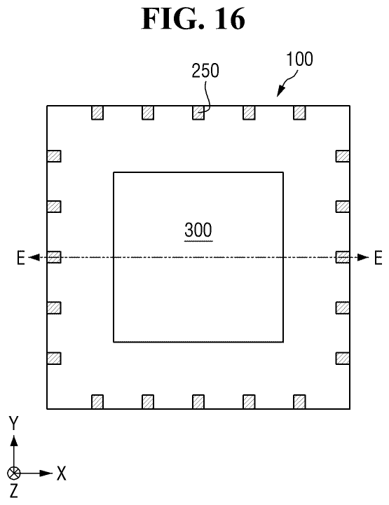

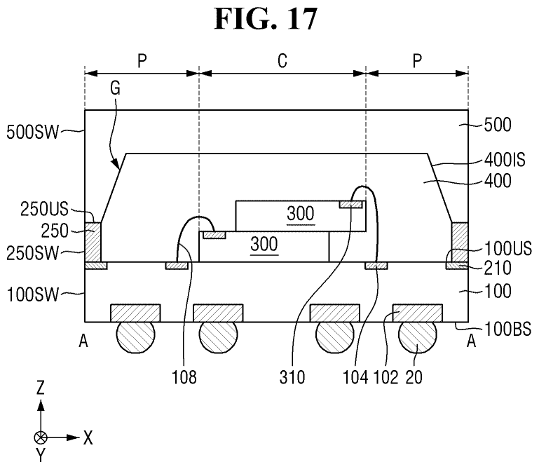

FIGS. 16 and 17 are drawings illustrating a semiconductor package according to embodiments of the present disclosure. FIG. 16 is a plan view of a semiconductor package according to embodiments of the present disclosure. FIG. 17 is a cross-sectional view taken along line E-E of FIG. 15. To the extent that an element is not described in detail with respect to this figure, it may be understood that the element is at least similar to a corresponding element that has been described elsewhere within the present disclosure, for example, with respect to FIGS. 1 through 3.

Referring to FIGS. 16 and 17, the semiconductor package, according to embodiments of the present disclosure, may include a circuit board 100, semiconductor chips 300, conductive pads 250, a molding 400, and an electromagnetic shield 500.

The conductive pads 250 may be disposed on an upper surface 100US of the circuit board 100. The conductive pads 250 may be connected to ground pads 210. The conductive pads 250 may simultaneously contact the circuit board 100, molding 400, and electromagnetic shield 500.

A groove G may be defined by upper surfaces 250US of the conductive pads 250 and inclined surfaces 400IS of the molding 400. The groove G may be formed up to the upper surfaces 250US of the conductive pads 250 using a laser drilling process after the formation of the molding 400 on the upper surface 100US of the circuit board 100.

The electromagnetic shield 500 may cover the upper surfaces 250US of the conductive pads 250 and the molding 400. The molding 400 may be surrounded by the electromagnetic shield 500 and the conductive pads 250.

Side surface 250SW of the conductive pads 250 may lie in common planes as corresponding side surface 500SW of the electromagnetic shield 500. The side surface 250SW of the conductive pads 250 may overlap with corresponding side surface 100SW of the circuit board 100 and the corresponding side surface 500SW of the electromagnetic shield 500 in a third direction Z.

The conductive pads 250 may include a metal material such as Al, Cu, Ni, W, Pt, or Au, but the present disclosure is not necessarily limited thereto.

Although embodiments of the present disclosure have been described with reference to the accompanying drawings, the present disclosure is not necessarily limited to the above embodiments and may be executed in various different forms. Thus, a person with ordinary skill in the technical field to which the present disclosure belongs will be able to understand that the present disclosure may be implemented in other specific forms without changing the technical idea or essential characteristics of the present disclosure.

What is claimed is:

1. A semiconductor package, comprising:
a circuit board;
semiconductor chips mounted on the circuit board;
a molding formed on the circuit board and covering each of the semiconductor chips;
an electromagnetic shield formed on the circuit board and covering the molding; and
ground wires connected to ground pads, which are installed on the circuit board,
wherein the ground wires penetrate the molding and the electromagnetic shield.

2. The semiconductor package of claim 1, wherein the ground wires are exposed from side surface of the electromagnetic shield.

3. The semiconductor package of claim 1, wherein the electromagnetic shield exposes side surface of the molding.

4. The semiconductor package of claim 1, wherein
the ground wires include first portions and second portions,
the molding envelops the first portions, and
the electromagnetic shield envelops the second portions.

5. The semiconductor package of claim 4, wherein
the first portions contact an upper surface of the circuit board, and
the second portions contact side surface of the molding.

6. The semiconductor package of claim 1, wherein the molding has a first upper surface, a second upper surface, which is higher than the first upper surface, and inclined surfaces, which connect the first and second upper surfaces to one another.

7. The semiconductor package of claim 6, wherein a first angle formed between the inclined surfaces and an imaginary extension of the first upper surface is an acute angle.

8. The semiconductor package of claim 1, wherein on side surface of the semiconductor package, the circuit board and the electromagnetic shield, including the ground wires, are sequentially stacked.

9. The semiconductor package of claim 8, wherein side surface of the circuit board, first surfaces of the ground wires, exposed from the electromagnetic shield, and side surface of the electromagnetic shield lie in common planes.

10. The semiconductor package of claim 8, wherein the molding is interposed between the circuit board and the electromagnetic shield.

11. The semiconductor package of claim 10, wherein side surface of the circuit board, side surface of the molding, first surfaces of the ground wires, exposed from the electromagnetic shield, and side surface of the electromagnetic shield lie in common planes.

12. The semiconductor package of claim 1, wherein
the molding includes a groove, which is formed at opposite ends of the molding,
parts of the ground wires are positioned in the groove, and
the electromagnetic shield fills the groove and covers the parts of the ground wires positioned in the groove.

13. A semiconductor package, comprising:
a circuit board including a center area and a peripheral area;
semiconductor chips mounted on the center area;
a molding formed on the circuit board, covering each of the semiconductor chips, and including a groove, which is formed at opposite ends of the molding;
an electromagnetic shield formed on the circuit board, filling the groove, and covering an upper surface of the molding; and
ground wires installed in the peripheral area and connected to ground pads, which are installed on the circuit board, the ground wires including first portions, which penetrate the molding, and second portions, which penetrate parts of the electromagnetic shield formed in the groove,
wherein the electromagnetic shield exposes the second portions.

14. The semiconductor package of claim 13, wherein the second portions of the ground wires are exposed on side surface of the electromagnetic shield.

15. The semiconductor package of claim 13, wherein
the first portions contact an upper surface of the circuit board, and
the second potions contact side surface of the electromagnetic shield.

16. The semiconductor package of claim 15, wherein
the molding has a first upper surface, which is positioned in the groove, and
the second portions of the ground wires overlap with the first upper surface and an upper surface of the circuit board in a vertical direction.

17. The semiconductor package of claim 16, wherein
the molding has a first upper surface, a second upper surface, which is higher than the first upper surface, and inclined surfaces, which connect the first and second upper surfaces to one another, and
a first angle formed between the inclined surfaces and an imaginary extension of the first upper surface is an acute angle.

18. A method of fabricating a semiconductor package, comprising:
providing a circuit board, which extends in a first direction, first semiconductor chips, which are disposed on the circuit board, second semiconductor chips, which are spaced apart from the first semiconductor chips in the first direction, on the circuit board, and ground wires, which are connected to ground pads that are installed on the circuit board;
forming a molding, which is formed on the circuit board and covers the first semiconductor chips, the second semiconductor chips, and the ground wires;
forming a groove, which is positioned at opposite ends of the molding, between the first semiconductor chips and the second semiconductor chips, in the molding through a laser drilling process, the groove exposing the ground wires; and
forming an electromagnetic shield, which covers an upper surface of the molding, fills the groove, and envelops the ground wires in the groove.

19. The method of claim 18, wherein in a cross-sectional view of the ground wires, taken in a direction perpendicular to an upper surface of the circuit board, sequentially stacking the circuit board, the molding, and the electromagnetic shield, including the ground wires.

20. The method of claim 18, wherein side surface of the molding, first surfaces of the ground wires, exposed from the electromagnetic shield, and side surface of the electromagnetic shield lie in common planes.
